(19) United States
(12) Patent Application Publication
(10) Pub. No.: US 2025/0183061 A1
(43) Pub. Date: Jun. 5, 2025

(54) SEMICONDUCTOR MANUFACTURING APPARATUS AND METHOD OF MANUFACTURING SEMICONDUCTOR DEVICE

(71) Applicant: Kioxia Corporation, Tokyo (JP)

(72) Inventors: Satoshi NAKAOKA, Yokkaichi Mie (JP); Hiroyasu IIMORI, Nagoya Aichi (JP)

(73) Assignee: Kioxia Corporation, Tokyo (JP)

(21) Appl. No.: 18/829,517

(22) Filed: Sep. 10, 2024

(30) Foreign Application Priority Data
Dec. 5, 2023 (JP) 2023-205491

(51) Int. Cl. H01L 21/67; H01L 21/306; H01L 21/677

(52) U.S. Cl. CPC H01L 21/67086; H01L 21/67757; H01L 21/30604

(57) ABSTRACT

The semiconductor manufacturing apparatus according to the embodiment includes a processing tank that stores a processing solution for processing wafers and circulates the stored processing solution, a first belt conveyor arranged to extend vertically within the processing tank, a second belt conveyor arranged to extend vertically within the processing tank, and a drive controller that opens and closes the first and second belt conveyors to sandwich and support ends of the wafers, and controls the first and second belt conveyors to rotate.

### CROSS-REFERENCE TO RELATED APPLICATIONS

This application is based upon and claims the benefit of priority from the prior Japanese Patent Application No. 2023-205491, filed on Dec. 5, 2023, the entire contents of which are incorporated herein by reference.

### FIELD

The present embodiment relates to a semiconductor manufacturing apparatus and a method of manufacturing the semiconductor device.

### BACKGROUND

Conventionally, there are semiconductor manufacturing devices that perform cleaning and etching processes by immersing wafers in a processing solution. In such semiconductor manufacturing devices, the processing solution is discharged from a jet tube and circulated in a processing tank. For example, near the jet tube's outlet, the temperature of the processing solution and the concentration and flow rate of the etchant are high, which increases the etching rate. As a result, differences in the processing amount (e.g., etching amount) occur above and below the wafer, reducing the in-plane uniformity of the processing on the wafer.

### BRIEF DESCRIPTION OF THE DRAWINGS

FIG. 1 is a diagram of the semiconductor manufacturing apparatus according to the first embodiment, showing an example of a state in which a wafer is processed.

FIG. 2 is a top view showing an example of a configuration focusing on a first region of the semiconductor manufacturing apparatus shown in FIG. 1.

FIG. 3 is a cross-sectional view showing an example of a configuration focusing on a second region of the semiconductor manufacturing apparatus shown in FIG. 1.

FIG. 4A is a cross-sectional view showing an example of a configuration focusing on a third region of the semiconductor manufacturing apparatus shown in FIG. 1.

FIG. 4B is a cross-sectional view showing another example of a configuration focusing on the third region of the semiconductor manufacturing apparatus shown in FIG. 1.

FIG. 5 is a diagram showing an example of a state in which a wafer is washed with a processing solution in a processing tank in the semiconductor manufacturing apparatus shown in FIG. 1.

FIG. 6A is an explanatory diagram showing an example of a manufacturing process of a semiconductor device by the semiconductor manufacturing apparatus according to the first embodiment.

FIG. 6B is an explanatory diagram showing an example of a manufacturing process of a semiconductor device by the semiconductor manufacturing apparatus according to the first embodiment, subsequent to FIG. 6A.

FIG. 7A is an explanatory diagram showing an example of a manufacturing process of a semiconductor device by the semiconductor manufacturing apparatus according to the first embodiment, subsequent to FIG. 6B.

FIG. 7B is an explanatory diagram showing an example of a manufacturing process of a semiconductor device by the semiconductor manufacturing apparatus according to the first embodiment, subsequent to FIG. 7A.

FIG. 8A is an explanatory diagram showing an example of a manufacturing process of a semiconductor device by the semiconductor manufacturing apparatus according to the first embodiment, subsequent to FIG. 7B.

FIG. 8B is an explanatory diagram showing an example of a manufacturing process of a semiconductor device by the semiconductor manufacturing apparatus according to the first embodiment, subsequent to FIG. 7A.

FIG. 9 is an explanatory diagram showing an example of a manufacturing process of a semiconductor device by the semiconductor manufacturing apparatus according to the first embodiment, subsequent to FIG. 8B.

### DETAILED DESCRIPTION

One embodiment aims to provide a semiconductor manufacturing apparatus and a method for manufacturing a semiconductor device that can improve the in-plane uniformity of processing on a wafer.

A semiconductor manufacturing apparatus according to one embodiment includes: a processing tank configured to store a processing solution for processing a wafer and circulate the processing solution stored in the processing tank; a first belt conveyor arranged to extend vertically within the processing tank; a second belt conveyor arranged to extend vertically within the processing tank; and a drive controller configured to open or close the first belt conveyor and the second belt conveyor so as to sandwich and support each end of the wafer, and to control driving of the first belt conveyor and the second belt conveyor to rotate the first belt conveyor and the second belt conveyor, wherein the drive controller rotates the first belt conveyor and the second belt conveyor to rotate the wafer about a direction perpendicular to the wafer surface and move the wafer vertically, in a state in which each end of the wafer immersed in the processing solution stored in the processing tank is sandwiched and supported by the first belt conveyor and the second belt conveyor.

The semiconductor manufacturing apparatus and the method for manufacturing a semiconductor device according to the embodiments will be described in detail below with reference to the accompanying drawings. It is noted that the present invention is not limited to these embodiments.

### First Embodiment

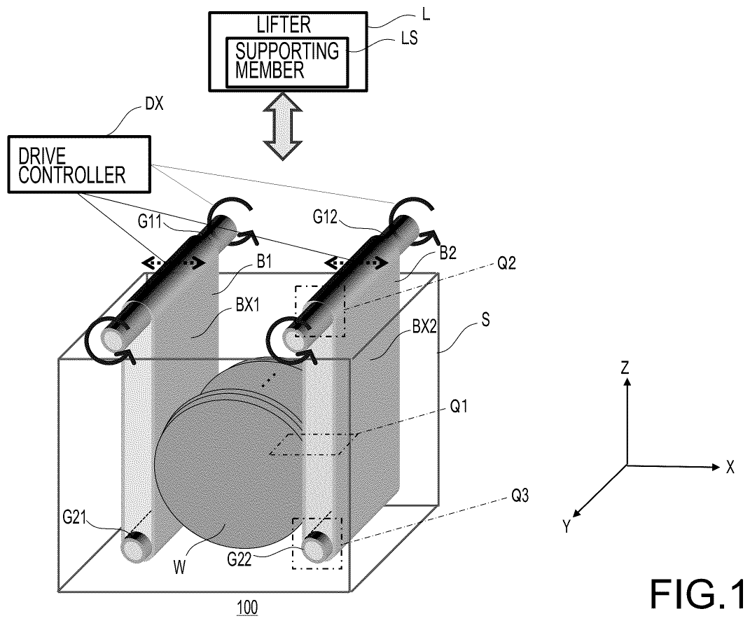

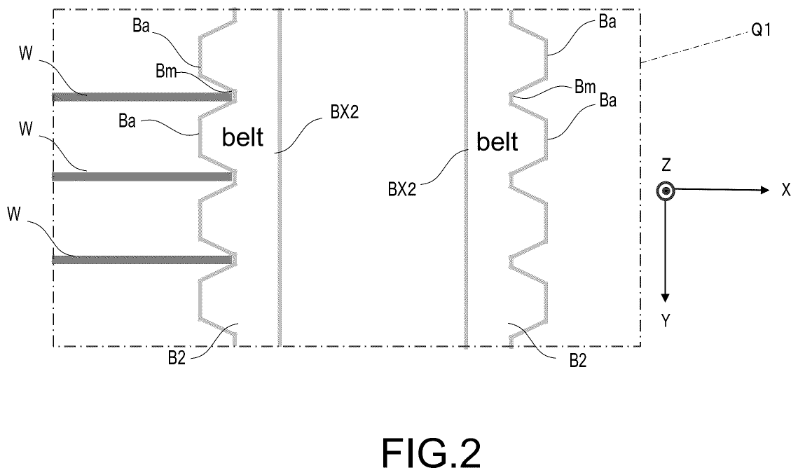

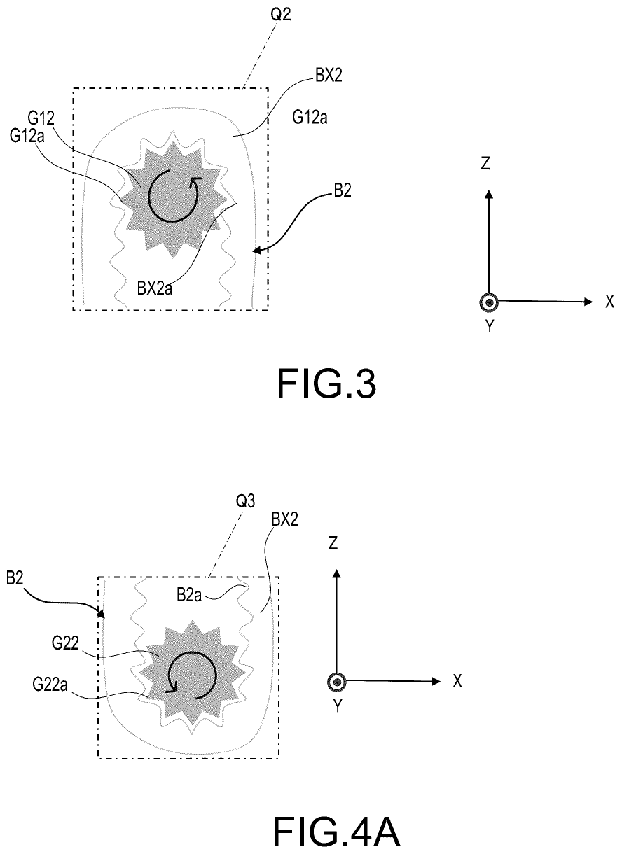

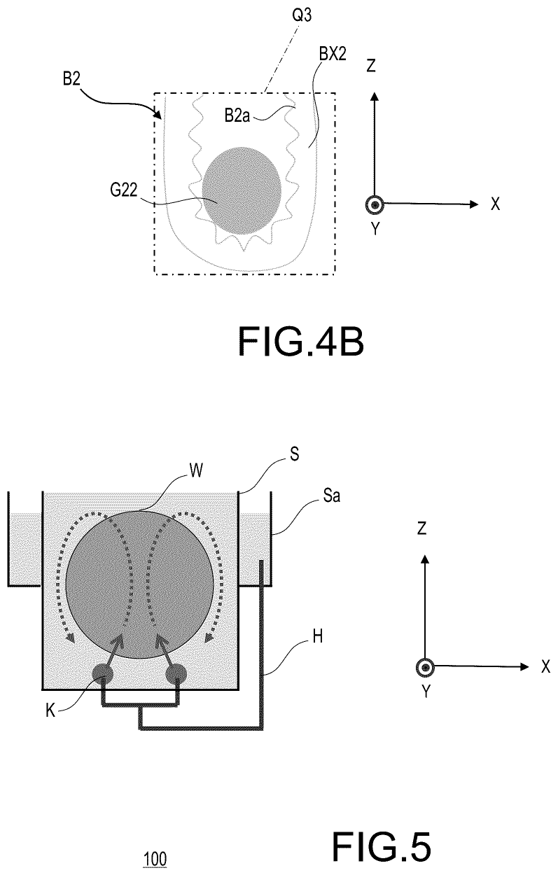

FIG. 1 is a diagram of the semiconductor manufacturing apparatus according to the first embodiment, showing an example of a state in which a wafer is processed. FIG. 2 is a top view showing an example of a configuration focusing on a first region of the semiconductor manufacturing apparatus shown in FIG. 1. FIG. 3 is a cross-sectional view showing an example of a configuration focusing on a second region of the semiconductor manufacturing apparatus shown in FIG. 1. FIG. 4A is a cross-sectional view showing an example of a configuration focusing on a third region of the semiconductor manufacturing apparatus shown in FIG. 1. FIG. 4B is a cross-sectional view showing another example of a configuration focusing on the third region of the semiconductor manufacturing apparatus shown in FIG. 1. FIG. 5 is a diagram showing an example of a state in which a wafer is washed with a processing solution in a processing tank in the semiconductor manufacturing apparatus shown in FIG. 1.

For simplicity, the processing solution stored in the processing tank S of the semiconductor manufacturing apparatus 100 is not shown in FIGS. 1 to 4. Furthermore, for simplicity, the auxiliary tank Sa, jet pipe H, and discharge unit K of the processing tank S shown in FIG. 5 are omitted in FIG. 1. Furthermore, for simplicity, the first belt conveyor B1, the second belt conveyor B2, the drive controller DX, and the lifter L shown in FIG. 1 are omitted in FIG. 5. Other configurations may be omitted in each drawing for convenience.

Furthermore, the configuration of the semiconductor manufacturing apparatus 100 according to the first embodiment is an example of the configuration of a batch-type apparatus that processes multiple wafers, but is not limited to this configuration and may be, for example, a single-wafer type apparatus.

### Semiconductor Manufacturing Apparatus

For example, as shown in FIGS. 1 to 5, the semiconductor manufacturing apparatus 100 includes a processing tank S, a first belt conveyor B1, a second belt conveyor B2, a drive controller DX, and a lifter L.

This semiconductor manufacturing apparatus 100 performs processes such as etching or cleaning of wafer W, by using a processing solution, which is a chemical liquid such as a cleaning liquid or an etching liquid. In this case, the processing solution is a chemical liquid such as hydrofluoric acid, phosphoric acid, or a metal mixed acid.

### Processing Tank

The processing tank S stores the processing solution used to process the wafers W and circulates the stored processing solution.

This processing tank S comprises, for example, an auxiliary tank Sa, a jet pipe H, and a discharge unit K, as shown in FIG. 5.

For example, as shown in FIG. 5, the discharge unit K is configured to discharge the processing solution, that has overflowed from the processing tank S into the auxiliary tank Sa, toward the wafer W via the jet pipe H.

In particular, the discharge unit K is configured to discharge the processing solution toward the wafer W so that the processing solution circulates through the processing tank S and passes over the surface of the wafer W, in the state that each end of the wafer W immersed in the processing solution is supported by the first belt conveyor B1 and the second belt conveyor B2.

### First Belt Conveyor

Furthermore, for example, as shown in FIG. 1, the first belt conveyor B1 is arranged to extend vertically (in the Z direction) within the processing tank S.

The upper part of the first belt conveyor B1 is located above the upper part of the processing tank S. The upper part of the first belt conveyor B1 can move laterally (for example, in the X direction perpendicular to the Z direction) relative to the processing tank S. The lower part of the first belt conveyor B1 is fixed to the housing of the processing tank S.

For example, similar to the example of the second belt conveyor B2 shown in FIG. 2, this first belt conveyor B1 includes a first belt BX in which grooves Bm, for supporting the lateral ends (X direction perpendicular to the Z direction) of the wafer W, are formed on the surface Ba of the first belt BX. This first belt BX1 is made of a material that has flexibility, chemical resistance, and heat resistance, such as polyvinyl alcohol (PVA), depending on the application.

Furthermore, for example, as shown in FIG. 1, the first belt conveyor B1 includes a first upper rotating shaft G11 and a first lower rotating shaft G21.

The first upper rotating shaft G11 is located at the top of the first belt conveyor B1 and extends laterally (in the Y direction perpendicular to the X and Z directions). Furthermore, this first upper rotating shaft G11 is arranged to be in contact with the first belt BX1 on the inside of the first belt BX1.

In addition, similar to the example of the second upper rotating shaft G12 shown in FIG. 3, the surface of this first upper rotating shaft G11 is formed with irregularities, and these irregularities mesh with the irregularities formed on the inner surface of the first belt BX1.

When the first upper rotating shaft G11 of the first belt conveyor B1 rotates, the first belt BX1 rotates, and the first belt conveyor B1 is driven to rotate.

Furthermore, the first lower rotating shaft G21 is located below the first belt conveyor B1 and extends laterally (in the Y direction). Furthermore, the first lower rotating shaft G21 contacts the first belt BX1 on the inside of the first belt BX1 and is fixed to the housing of the processing tank S.

### Second Belt Conveyor

The second belt conveyor B2 is also arranged to extend vertically (in the Z direction in FIG. 1) within the processing tank S, for example, as shown in FIG. 1.

The upper part of the second belt conveyor B2 is located above the upper part of the processing tank S, for example, as shown in FIG. 1. The upper part of the second belt conveyor B2 is movable laterally (for example, in the X direction in FIG. 1) relative to the processing tank S. The lower part of the second belt conveyor B2 is fixed to the housing of the processing tank S. The second belt conveyor B2 is also arranged to extend vertically (in the Z direction in FIG. 1) within the processing tank S, for example, as shown in FIG. 1.

For example, as shown in FIG. 2, the second belt conveyor B2 includes a second belt BX2 in which a groove Bm is formed on the surface BA to support the end of the wafer W in the lateral direction (in the X direction in FIG. 2). The second belt BX2 is made of a material that has flexibility, chemical resistance, and heat resistance, such as polyvinyl alcohol (PVA), depending on the application.

Then, the first belt conveyor B1 and the second belt conveyor B2 described above are the closed state so as to sandwich and support each end of the wafer W. The wafer W is supported by the groove Bm of the first belt BX1 of the first belt conveyor B1 and the groove Bm of the second belt BX2 of the second belt conveyor B2 described above.

The second belt conveyor B2 also includes, for example, a second upper rotating shaft G12 and a second lower rotating shaft G22, as shown in FIG. 1.

The second upper rotating shaft G12 is located above the second belt conveyor B2 and extends in the Y direction. Furthermore, this second upper rotating shaft G12 is configured to contact the second belt BX2 on the inside of the second belt BX2. In the example shown in FIG. 3, bumps and dips G12a are formed on the surface of this second upper rotating shaft G12, and these bumps and dips G12a mesh with the irregularities BX2a formed on the inner surface of the second belt BX2. The irregularities on the inside of the second belt BX2 shown in FIG. 3 may be of a different shape, or may not be formed at all.

When the second upper rotating shaft G12 of the second belt conveyor B2 rotates, the second belt BX2 rotates, and the second belt conveyor B2 is driven to rotate.

Also, for example, as shown in FIG. 1, the second lower rotating shaft G22 is located below the second belt conveyor B2 and extends laterally (in the Y direction). Furthermore, the second lower rotating shaft G22 contacts the second belt BX2 on the inside of the second belt BX2 and is fixed to the housing of the processing tank S.

Here, in the example shown in FIG. 4A, the second lower rotating shaft G22 has a surface on which bumps and dips G22a are formed, and these bumps and dips G22a mesh with the irregularities BX2a formed on the inner surface of the second belt BX2. In this case, the second lower rotating shaft G22 rotates around the Y direction while its position is fixed to the housing of the processing tank S, by rotating the second belt BX2.

On the other hand, in the example shown in FIG. 4B, the surface of the second lower rotating shaft G22 has no bumps and dips. In this case, even if the second belt BX2 rotates, the second lower rotating shaft G22 does not rotate, or it may rotate around the Y direction, when the second lower rotating shaft G22 is in a state where its position is fixed to the housing of the processing tank S.

The first belt conveyor B1 and the second belt conveyor B2 may each have a fixed plate (not shown) inside to ensure their rigidity. For example, this fixed plate may be made of a material such as a fluorine resin or a quartz.

### Lifter

Furthermore, the lifter L is configured to move the wafer W from above into the processing tank S and immerse it in the processing solution to process the wafer W. On the other hand, the lifter L is configured to lift the wafer W that has completed processing upward from inside the processing tank S.

This lifter L is equipped with a supporting member LS that supports the wafer W from below, for example, when moving the wafer W vertically (in the Z direction).

### Drive Controller

For example, as shown in FIG. 1, the drive controller DX is configured to open and close the first belt conveyor B1 and the second belt conveyor B2 so as to support each end of the wafer W by sandwiching them. The drive controller DX may also be configured to control the operation of the lifter L, as well as the operation of the first belt conveyor B1 and the second belt conveyor B2, as necessary.

As shown in FIG. 1, the drive controller DX controls the opening and closing operations of the first belt conveyor B1 and the second belt conveyor B2 by moving the first upper rotating shaft G11 and the second upper rotating shaft G12 laterally.

For example, the drive controller DX is configured to control the state from a closed state to an open state, by driving the first belt conveyor B1 and the second belt conveyor B2 so that their upper parts move away from each other.

On the other hand, the drive controller DX is designed to control the state from the open state to the closed state, by driving the first belt conveyor B1 and the second belt conveyor B2 so that their upper parts approach each other.

In particular, the drive controller DX operates the first belt conveyor B1 and the second belt conveyor B2 from an open state to a closed state so as to sandwich and support the end of the wafer W. in the state that the wafer W is moved from above into the processing tank S by the lifter L.

In this way, the drive controller DX controls the state in which each end of the wafer W immersed in the processing solution stored in the processing tank S is sandwiched and supported by the first belt conveyor B1 and the second belt conveyor B2, by this opening and closing operation. In particular, the drive controller DX is configured to move the upper part of the first belt conveyor B1 and the upper part of the second belt conveyor B2, in order to adjust the pressure for the first belt conveyor B1 and the second belt conveyor B2 to sandwich and support each end of the wafer W.

Furthermore, the drive controller DX is configured to control to drive the first belt conveyor B1 and the second belt conveyor B2 to rotate.

The drive controller DX controls the rotational drive of the first belt conveyor B1 and the second belt conveyor B2 by rotating the first belt BX1 and the second belt BX2 by rotating the first upper rotating shaft G11 and the second upper rotating shaft G12 shown in FIG. 1.

It is noted that this drive controller DX may also include a motor (not shown) that rotates the first upper rotating shaft G11 and the second upper rotating shaft G12 to drive the first belt conveyor B1 and the second belt conveyor B2.

The drive controller DX may also be configured to reverse the rotation direction of the wafer W, in a state that each end of the wafer W immersed in the processing solution being supported by the first belt conveyor B1 and the second belt conveyor B2.

In this way, the drive controller DX rotates the first belt conveyor B1 and the second belt conveyor B2, in the state that each end of the wafer W immersed in the processing solution stored in the processing tank S is supported by the first belt conveyor B1 and the second belt conveyor B2. Thus, the drive controller DX rotates the wafer W around the direction perpendicular to the surface of the wafer W (Y direction) and the drive controller DX moves the wafer W in the vertical direction (in the Z direction).

As described above, the semiconductor manufacturing apparatus 100 according to the first embodiment discharges the processing solution from the jet pipe to circulate the processing solution in the processing tank. For example, near the discharge unit K of the jet pipe H, the temperature of the processing solution, the concentration of the etchant in the processing solution, and the flow rate of the processing solution are high, so that the etching rate increases.

However, this semiconductor manufacturing apparatus 100 rotates the wafer W around the direction (the Y direction) perpendicular to the surface of the wafer W and moves the wafer W in the vertical direction (in the Z direction), by driving to rotate the first belt conveyor B1 and the second belt conveyor B2, in the state that each end of the wafer W immersed in the processing solution stored in the processing tank S is supported by the first belt conveyor B1 and the second belt conveyor B2.

This makes it possible to control the rotation direction of the wafer W during processing. Therefore, while the wafer W is being processed, it is possible to lower, raise, and rotate the wafer W. Therefore, the positions at which the processing solution hits the wafer W are dispersed. As a result, the difference in the amount of processing (e.g., the amount of etching) within the surface of the wafer W in the vertical and lateral directions is reduced.

In other words, the semiconductor manufacturing apparatus 100 according to the first embodiment can improve the in-plane uniformity of processing on the wafer W.

### Method of Manufacturing a Semiconductor Device

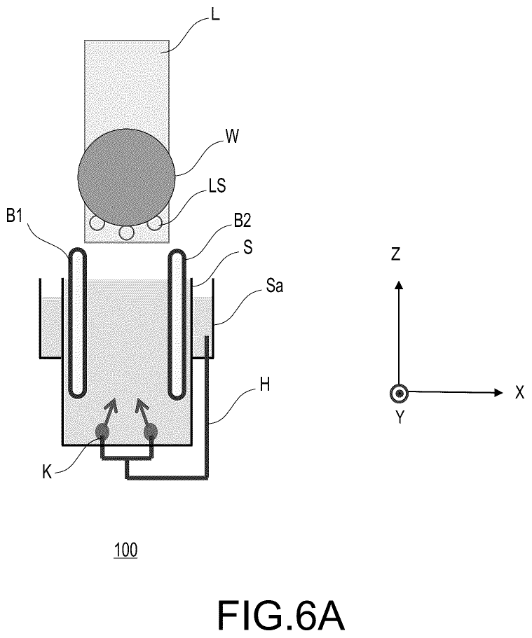

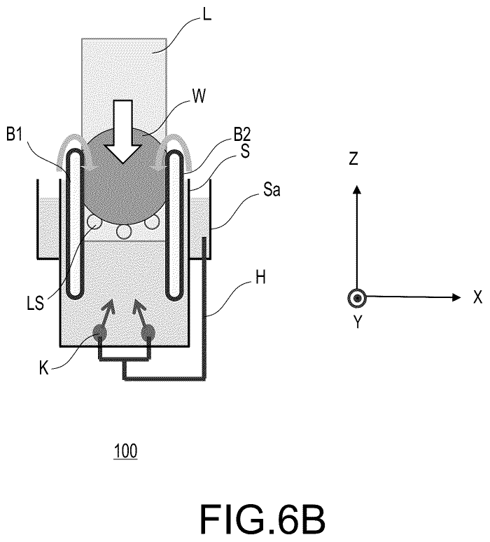

Next, as described above, an example of a method of manufacturing a semiconductor device using the semiconductor manufacturing apparatus 100 according to the first embodiment will be described with reference to FIGS. 6A to 9. FIGS. 6A to 9 are explanatory diagrams showing an example of a manufacturing process of a semiconductor device using the semiconductor manufacturing apparatus 100 according to the first embodiment shown in FIG. 1.

It is note that in FIGS. 6A to 9, for simplicity, the drive controller DX is omitted, and the configuration of the first and second belt conveyors B1 and B2 is shown in a simplified form.

First, as shown in FIG. 6A, for example, a wafer W processed in a previous step is transferred to lifter L so that the wafer W is supported by supporting member LS of lifter L.

Next, as shown in FIG. 6B, the drive controller DX lowers the lifter L and rotates the first and second belt conveyors in accordance with the operation of the lifter L. If necessary, the drive controller DX operates the first belt conveyor B1 and the second belt conveyor B2 to the open state relative to each end of the wafer W, in order to move the wafer W from the lifter L to between the first and second belt conveyors B1 and B2 in the processing tank S.

Then, the drive controller DX operates the first belt conveyor B1 and the second belt conveyor B2 from the open state to the closed state so as to sandwich and support each end of the wafer W, in the state that the wafer W moved from above into the processing tank S by the lifter L.

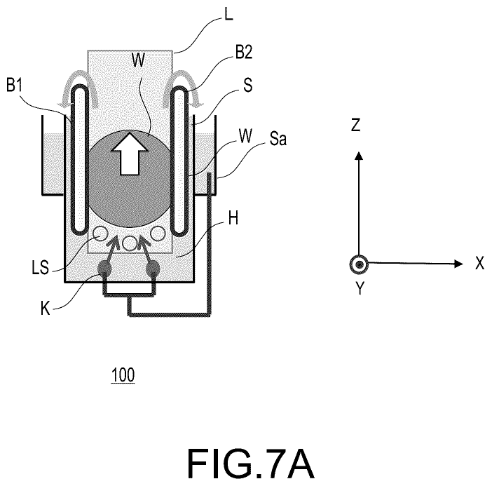

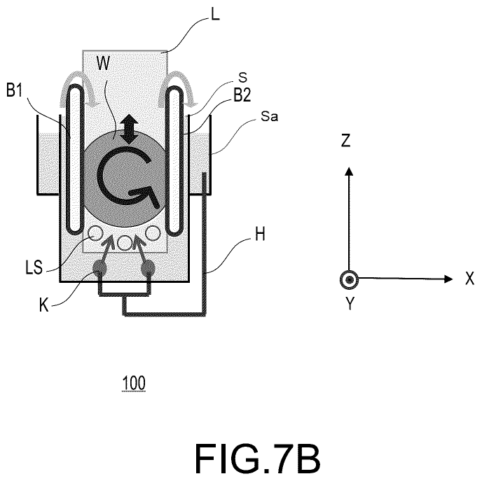

Next, as shown in FIG. 7A, the drive controller DX drives the first and second belt conveyors B1 and B2 to rotate so as to slightly lift the wafer W from the lifter L. Alternatively, while the wafer W is supported by the first and second belt conveyors B1 and B2, the drive controller DX may further lower the lifter L so as to slightly lift the wafer W from the lifter L.

As a result, the wafer W is separated from the lifter L and the wafer W is in the state that the wafer W is supported by the first and second belt conveyors B1 and B2.

Next, as shown in FIG. 7B, the drive controller DX rotates the wafer W around the direction (the Z direction) perpendicular to the surface of the wafer W (Y direction) and moves the wafer W in the vertical direction (swings up and down), by driving the first belt conveyor B1 and the second belt conveyor B2 to rotate, in the state that each end of the wafer W immersed in the processing solution stored in the processing tank S is sandwiched and supported by the first belt conveyor B1 and the second belt conveyor B2.

As mentioned above, the drive controller DX may be configured to reverse the rotation direction of the wafer W, in the state that each end of the wafer W immersed in the processing solution being supported by the first belt conveyor B1 and the second belt conveyor B2.

As a result, the positions at which the processing solution hits the wafer W are dispersed, and the difference in the amount of processing (e.g., the amount of etching) within the surface of the wafer W in the vertical and lateral directions is reduced.

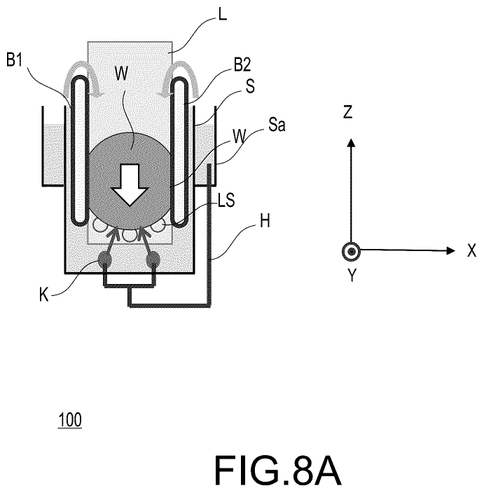

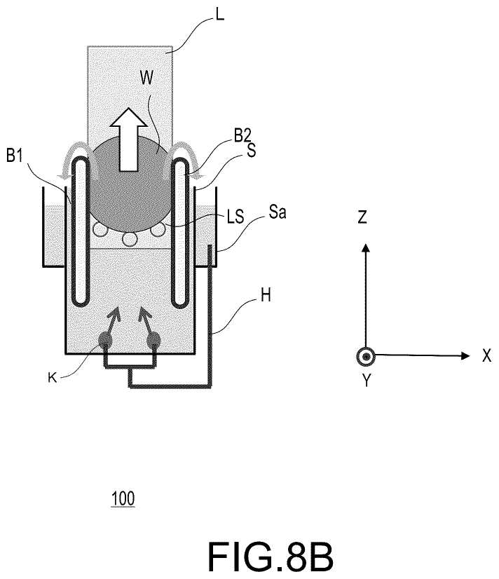

Next, as shown in FIG. 8A, the drive controller DX drives the first and second belt conveyors B1 and B2 to rotate so as to load the wafer W onto the lifter L. Alternatively, the drive controller DX may further raise the lifter L while the wafer W is supported by the first and second belt conveyors B1 and B2 so as to load the wafer W onto the lifter L. As a result, the wafer W is loaded onto the lifter L.

Next, as shown in FIG. 8B, the drive controller DX raises the lifter L, and drives the first and second belt conveyors to rotate in accordance with the rise of the wafer W caused by the rise of the lifter L. If necessary, the drive controller DX operates the first belt conveyor B1 and the second belt conveyor B2 from a closed state in which each end of the wafer W is sandwiched and supported to an open state so that the processed wafer W can be pulled up from inside the processing tank S by the lifter L.

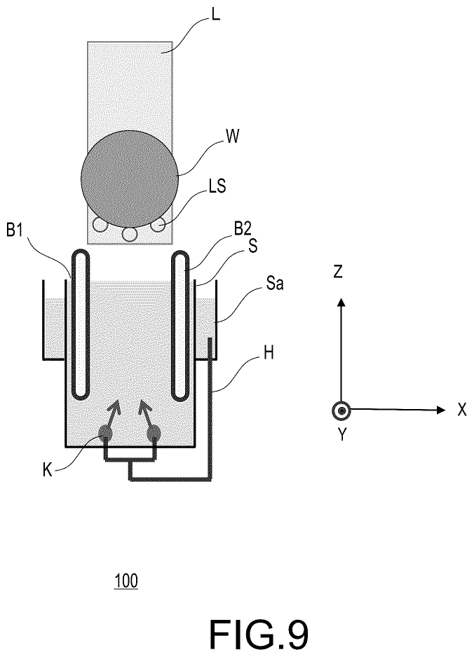

Next, as shown in FIG. 9, the drive controller DX further raises the lifter L while the wafer W is supported by the supporting member LS of the lifter L. Then, the wafer W, that has completed this processing, is handed over from the lifter L to the next process.

Thus, in the method of manufacturing a semiconductor device using the semiconductor manufacturing apparatus 100 according to the first embodiment, the first belt conveyor B1 and the second belt conveyor B2 are driven to rotate, in the state that each end of the wafer W immersed in the processing solution stored in the processing tank S is supported by being sandwiched between the first belt conveyor B1 and the second belt conveyor B2. In this way, the wafer W is rotated around the direction perpendicular to the surface of the wafer W (Y direction), and the wafer W is moved in the vertical direction (in the Z direction).

As a result, the positions where the processing solution hits the wafer W are dispersed, so that the difference in the amount of processing (for example, the amount of etching) in the vertical and lateral directions of the wafer W is reduced.

As described above, the method for manufacturing a semiconductor device using the semiconductor manufacturing apparatus of this embodiment can improve the in-plane uniformity of processing on the wafer W.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a processing tank configured to store a processing solution for processing a wafer and circulate the processing solution stored in the processing tank;
a first belt conveyor arranged to extend vertically within the processing tank;
a second belt conveyor arranged to extend vertically within the processing tank; and
a drive controller configured to open or close the first belt conveyor and the second belt conveyor so as to sandwich and support each end of the wafer, and to control driving of the first belt conveyor and the second belt conveyor to rotate the first belt conveyor and the second belt conveyor,
wherein the drive controller rotates the first belt conveyor and the second belt conveyor to rotate the wafer about a direction perpendicular to the wafer surface and move the wafer vertically, in a state in which each end of the wafer immersed in the processing solution stored in the processing tank is sandwiched and supported by the first belt conveyor and the second belt conveyor.

2. The semiconductor manufacturing apparatus according to claim 1,
wherein the drive controller controls to move an upper part of the first belt conveyor and an upper part of the second belt conveyor, to adjust pressure for supporting each end of the wafer by the first belt conveyor and the second belt conveyor.

3. The semiconductor manufacturing apparatus according to claim 1,
wherein the drive controller controls a state of the first belt conveyor and the second belt conveyor from a closed state to an open state by driving an upper part of the first belt conveyor and an upper part of the second belt conveyor to move away from each other, and
wherein the drive controller controls the state of the first belt conveyor and the second belt conveyor from the open state to the closed state by driving the upper part of the first belt conveyor and the upper part of the second belt conveyor to move closer to each other.

4. The semiconductor manufacturing apparatus according to claim 2,
wherein the drive controller controls a state of the first belt conveyor and the second belt conveyor from a closed state to an open state by driving an upper part of the first belt conveyor and an upper part of the second belt conveyor to move away from each other, and
wherein the drive controller controls the state of the first belt conveyor and the second belt conveyor from the open state to the closed state by driving the upper part of the first belt conveyor and the upper part of the second belt conveyor to move closer to each other.

5. The semiconductor manufacturing apparatus according to claim 1, further comprising:
a lifter configured to move the wafer from above into the processing tank and immerse the wafer in the processing solution in order to process the wafer, and to lift the wafer, which has been processed, from inside the processing tank upward,
wherein the drive controller operates the first belt conveyor and the second belt conveyor from an open state to a closed state so as to sandwich and support each end of the wafer, in a state in which the wafer is moved from above into the processing tank by the lifter, and
wherein the drive controller operates the first belt conveyor and the second belt conveyor from the closed state in which the first belt conveyor and the second belt conveyor sandwich and support each end of the wafer to the open state, and operates the lifter to lift the wafer, which has been processed, from inside the processing tank upward.

6. The semiconductor manufacturing apparatus according to claim 2, further comprising:
a lifter configured to move the wafer from above into the processing tank and immerse the wafer in the processing solution in order to process the wafer, and to lift the wafer, which has been processed, from inside the processing tank upward,
wherein the drive controller operates the first belt conveyor and the second belt conveyor from an open state to a closed state so as to sandwich and support each end of the wafer, in a state in which the wafer is moved from above into the processing tank by the lifter, and
wherein the drive controller operates the first belt conveyor and the second belt conveyor from the closed state in which the first belt conveyor and the second belt conveyor sandwich and support each end of the wafer to the open state, and operates the lifter to lift the wafer, which has been processed, from inside the processing tank upward.

7. The semiconductor manufacturing apparatus according to claim 3, further comprising:
a lifter configured to move the wafer from above into the processing tank and immerse the wafer in the processing solution in order to process the wafer, and to lift the wafer, which has been processed, from inside the processing tank upward,
wherein the drive controller operates the first belt conveyor and the second belt conveyor from an open state to a closed state so as to sandwich and support each end of the wafer, in a state in which the wafer is moved from above into the processing tank by the lifter, and
wherein the drive controller operates the first belt conveyor and the second belt conveyor from the closed state in which the first belt conveyor and the second belt conveyor sandwich and support each end of the wafer to the open state, and operates the lifter to lift the wafer, which has been processed, from inside the processing tank upward.

8. The semiconductor manufacturing apparatus according to claim 1,
wherein the processing tank includes a discharge unit configured to discharge the processing solution overflowing from the processing tank toward the wafer so that the processing solution circulates through the surface of the wafer within the processing tank, in a state that each end of the wafer immersed in the processing solution is sandwiched and supported by the first belt conveyor and the second belt conveyor.

9. The semiconductor manufacturing apparatus according to claim 2,
wherein the processing tank includes a discharge unit configured to discharge the processing solution overflowing from the processing tank toward the wafer so that the processing solution circulates through the surface of the wafer within the processing tank, in a state that each end of the wafer immersed in the processing solution is sandwiched and supported by the first belt conveyor and the second belt conveyor.

10. The semiconductor manufacturing apparatus according to claim 3,
wherein the processing tank includes a discharge unit configured to discharge the processing solution overflowing from the processing tank toward the wafer so that the processing solution circulates through the surface of the wafer within the processing tank, in a state that each end of the wafer immersed in the processing solution is sandwiched and supported by the first belt conveyor and the second belt conveyor.

11. A method for manufacturing a semiconductor device, using a semiconductor manufacturing apparatus comprises a processing tank configured to store a processing solution for processing a wafer and circulate the processing solution stored in the processing tank; a first belt conveyor arranged to extend vertically within the processing tank; a second belt conveyor arranged to extend vertically within the processing tank; and a drive controller configured to open or close the first belt conveyor and the second belt conveyor so as to sandwich and support each end of the wafer, and to control driving of the first belt conveyor and the second belt conveyor to rotate the first belt conveyor and the second belt conveyor, the method comprising:
rotating, by the drive controller, the first belt conveyor and the second belt conveyor to rotate the wafer about a direction perpendicular to the wafer surface and move the wafer vertically, in a state in which each end of the wafer immersed in the processing solution stored in the processing tank is sandwiched and supported by the first belt conveyor and the second belt conveyor.

12. The method for manufacturing the semiconductor device according to claim 11,
wherein the drive controller controls to move an upper part of the first belt conveyor and an upper part of the second belt conveyor, to adjust pressure for supporting each end of the wafer by the first belt conveyor and the second belt conveyor.

13. The method for manufacturing the semiconductor device according to claim 11,
wherein the drive controller controls a state of the first belt conveyor and the second belt conveyor from a closed state to an open state by driving an upper part of the first belt conveyor and an upper part of the second belt conveyor to move away from each other, and
wherein the drive controller controls the state of the first belt conveyor and the second belt conveyor from the open state to the closed state by driving the upper part of the first belt conveyor and the upper part of the second belt conveyor to move closer to each other.

14. The method for manufacturing the semiconductor device according to claim 12,
wherein the drive controller controls a state of the first belt conveyor and the second belt conveyor from a closed state to an open state by driving an upper part of the first belt conveyor and an upper part of the second belt conveyor to move away from each other, and
wherein the drive controller controls the state of the first belt conveyor and the second belt conveyor from the open state to the closed state by driving the upper part of the first belt conveyor and the upper part of the second belt conveyor to move closer to each other.

15. The method for manufacturing the semiconductor device according to claim 11,
wherein the semiconductor manufacturing apparatus further comprising:
a lifter configured to move the wafer from above into the processing tank and immerse the wafer in the processing solution in order to process the wafer, and to lift the wafer, which has been processed, from inside the processing tank upward,
wherein the drive controller operates the first belt conveyor and the second belt conveyor from an open state to a closed state so as to sandwich and support each end of the wafer, in a state in which the wafer is moved from above into the processing tank by the lifter, and
wherein the drive controller operates the first belt conveyor and the second belt conveyor from the closed state in which the first belt conveyor and the second belt conveyor sandwich and support each end of the wafer to the open state, and operates the lifter to lift the wafer, which has been processed, from inside the processing tank upward.

16. The method for manufacturing the semiconductor device according to claim 12,
wherein the semiconductor manufacturing apparatus further comprising:
a lifter configured to move the wafer from above into the processing tank and immerse the wafer in the processing solution in order to process the wafer, and to lift the wafer, which has been processed, from inside the processing tank upward,
wherein the drive controller operates the first belt conveyor and the second belt conveyor from an open state to a closed state so as to sandwich and support each end of the wafer, in a state in which the wafer is moved from above into the processing tank by the lifter, and
wherein the drive controller operates the first belt conveyor and the second belt conveyor from the closed state in which the first belt conveyor and the second belt conveyor sandwich and support each end of the wafer to the open state, and operates the lifter to lift the wafer, which has been processed, from inside the processing tank upward.

17. The method for manufacturing the semiconductor device according to claim 13,
wherein the semiconductor manufacturing apparatus further comprising:
a lifter configured to move the wafer from above into the processing tank and immerse the wafer in the processing solution in order to process the wafer, and to lift the wafer, which has been processed, from inside the processing tank upward,
wherein the drive controller operates the first belt conveyor and the second belt conveyor from an open state to a closed state so as to sandwich and support each end of the wafer, in a state in which the wafer is moved from above into the processing tank by the lifter, and
wherein the drive controller operates the first belt conveyor and the second belt conveyor from the closed state in which the first belt conveyor and the second belt conveyor sandwich and support each end of the wafer to the open state, and operates the lifter to lift the wafer, which has been processed, from inside the processing tank upward.

18. The method for manufacturing the semiconductor device according to claim 11,
wherein the processing tank includes a discharge unit configured to discharge the processing solution overflowing from the processing tank toward the wafer so that the processing solution circulates through the surface of the wafer within the processing tank, in a state that each end of the wafer immersed in the processing solution is sandwiched and supported by the first belt conveyor and the second belt conveyor.

19. The method for manufacturing the semiconductor device according to claim 12,
wherein the processing tank includes a discharge unit configured to discharge the processing solution overflowing from the processing tank toward the wafer so that the processing solution circulates through the surface of the wafer within the processing tank, in a state that each end of the wafer immersed in the processing solution is sandwiched and supported by the first belt conveyor and the second belt conveyor.

20. The method for manufacturing the semiconductor device according to claim 13,
wherein the processing tank includes a discharge unit configured to discharge the processing solution overflowing from the processing tank toward the wafer so that the processing solution circulates through the surface of the wafer within the processing tank, in a state that each end of the wafer immersed in the processing solution is sandwiched and supported by the first belt conveyor and the second belt conveyor.
